(19) United States
(12) Patent Application Publication
(10) Pub. No.: US 2007/0235797 A1
(43) Pub. Date: Oct. 11, 2007

(54) Process for reducing a size of a compact EEPROM device

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/393,145

(22) Filed: Mar. 29, 2006

(51) Int. Cl. H01L 29/788; H01L 21/336

(52) U.S. Cl. 257/315; 257/316; 438/257; 438/266

(57) ABSTRACT

The present invention is a method, and resulting device, for fabricating memory cells with an extremely small area. The small area requirement is met due primarily to two significant factors. First, a judicious use of spacers allows a control gate/wordline or select line to be fabricated in extremely close proximity to an associated plurality of floating gates. Additionally, each of the plurality of floating gates is supplied with a majority carrier (e.g., electrons) through a charge injector. Each of the plurality of injector regions is made by doping a localized area (e.g., through injector ion implantation) creating a subsurface highly-doped region that is setup to receive bias from a nearby contact for charge generation, i.e., a tunneling injector.

### TECHNICAL FIELD

The invention relates to non-volatile memory arrays and, in particular, to a compact architectural arrangement for fabrication of non-volatile memory devices and a method of making same.

### BACKGROUND ART

A non-volatile memory device is both electrically erasable and programmable. Such a device retains data even after power to the device is terminated. One particular type of non-volatile memory device is an electrically erasable programmable read only memory (EEPROM) device. In an EEPROM device, programming and erasing are accomplished by transferring electrons to and from a floating gate electrode through a thin dielectric layer, known as a tunnel-oxide layer, located between the floating gate electrode and an underlying substrate. Typically, electron transfer is carried out by either hot electron injection or by Fowler-Nordheim tunneling. In either electron transfer mechanism, a voltage is coupled to the floating gate electrode by a control gate electrode, also known as a programming region. The control gate electrode or programming region is capacitively coupled to the floating gate electrode such that a voltage applied to the programming region is coupled to the floating gate electrode.

A traditional EEPROM device utilizes the floating gate, in a field effect transistor structure, positioned over but insulated from a channel region in the semiconductor substrate, and between source and drain regions. A threshold voltage characteristic of the transistor is controlled by an amount of charge that is retained on the floating gate. Thus, a minimum amount of voltage (i.e., the threshold voltage) must be applied to the control gate before the transistor is turned “on” to permit conduction between source and drain regions of the transistor is controlled by the amount of charge on the floating gate. A memory transistor is programmed to one of two states by accelerating electrons from the substrate channel region, through a thin dielectric tunnel layer and onto the floating gate.

A state of the memory transistor is read by placing an operating voltage across the source and drain with an additional voltage on the control gate of the memory transistor. A level of current flowing between the source and drain is detected to determine whether the device is programmed to be “on” or “off” for a given control gate voltage. A specific single memory transistor cell in a two-dimensional array of EEPROM memory cells is addressed for reading by (1) applying a source-drain voltage to source and drain lines in a column containing the cell being addressed, and; (2) applying a control gate voltage to the control gates in a row containing the cell being addressed.

As discussed, EEPROM memory cells may be erased electrically. One way in which the cell is erased electrically is by transfer of charge from the floating gate to the transistor drain through thin tunnel dielectric layer. Charge transfer is again accomplished by applying appropriate voltages to the source, drain, and control gate of the floating gate transistor. An array of EEPROM cells is generally referred to as a Flash EEPROM array because an entire array of cells, or a significant group of cells, is erased simultaneously.

As Flash EEPROM arrays become increasingly larger in terms of storage capacity, the semiconductor industry has attempted various ways of reducing a size of individual memory cells, and thus, reducing a size of the entire array. The size reduction however cannot impact reliability of the memory device.

### SUMMARY

The present invention is a method, and resulting device, for fabricating memory cells with extremely small geometrical features. The small area requirement is met due primarily to two significant factors. First, a judicious use of spacers, described in detail herein, allows a control gate/wordline. Select line, or other structure to be fabricated in extremely close proximity to, for example, an associated plurality of floating gates. Additionally, each of the plurality of floating gates is supplied with carriers (i.e., electrons or holes) through a plurality of charge injectors. Each of the plurality of charge injector regions is made by doping a localized area (e.g., through injector ion implantation), thereby creating a subsurface highly-doped region that receives bias from a nearby contact for charge generation, i.e., a tunneling injector.

In one exemplary embodiment, the present invention is a method of fabricating an electronic integrated circuit device on a first surface of a substrate (e.g., a silicon wafer). The method includes forming a semiconducting film layer on the substrate. In the case of a silicon wafer, a first dielectric layer, such as silicon dioxide, is first formed (e.g., thermally or deposited). An additional dielectric film layer is then formed over the semiconducting film layer. An aperture is created and spacers are formed on sidewalls of the aperture. The spacers are produced such that a distance between spacers on opposing sidewalls of the aperture is less than a limit of optical photolithography. An injector dopant region is then formed within the aperture created by the spacers. The semiconducting film layer underlying the second aperture is etched, thus forming a floating gate and a wordline.

The present invention is also a device produced using methods detailed herein. The device, in one exemplary embodiment, is a memory cell array that includes a plurality of floating gates forming a portion of a memory transistor. The plurality of floating gates are comprised substantially of a first semiconducting material, for example, polysilicon, and are constructed over a substrate with a gate dielectric material interposed between the plurality of floating gates and the substrate. A combination control gate/wordline is fabricated in close proximity to the plurality of floating gates with the wordline arranged such that a distance between a long axis of the wordline and a nearest portion of any of the plurality of floating gates is less than a limit of resolution of optical photolithography. An injector dopant region is disposed in close relationship to each of the plurality of floating gates.

### BRIEF DESCRIPTION OF THE DRAWINGS

FIGS. 1A-1E show exemplary process steps employing a spacer application used in an embodiment of the present invention.

FIG. 2 shows a simplified portion of an exemplary memory array employing the spacer and charge injector fabrication techniques outlined with regard to FIGS. 1A-1E.

FIG. 3 shows an exemplary embodiment of a memory array portion incorporating the spacer technique outlined with regard to FIGS. 1A-1E.

FIG. 4 shows another exemplary embodiment of a memory array portion incorporating the spacer technique outlined with regard to FIGS. 1A-1E.

### DETAILED DESCRIPTION

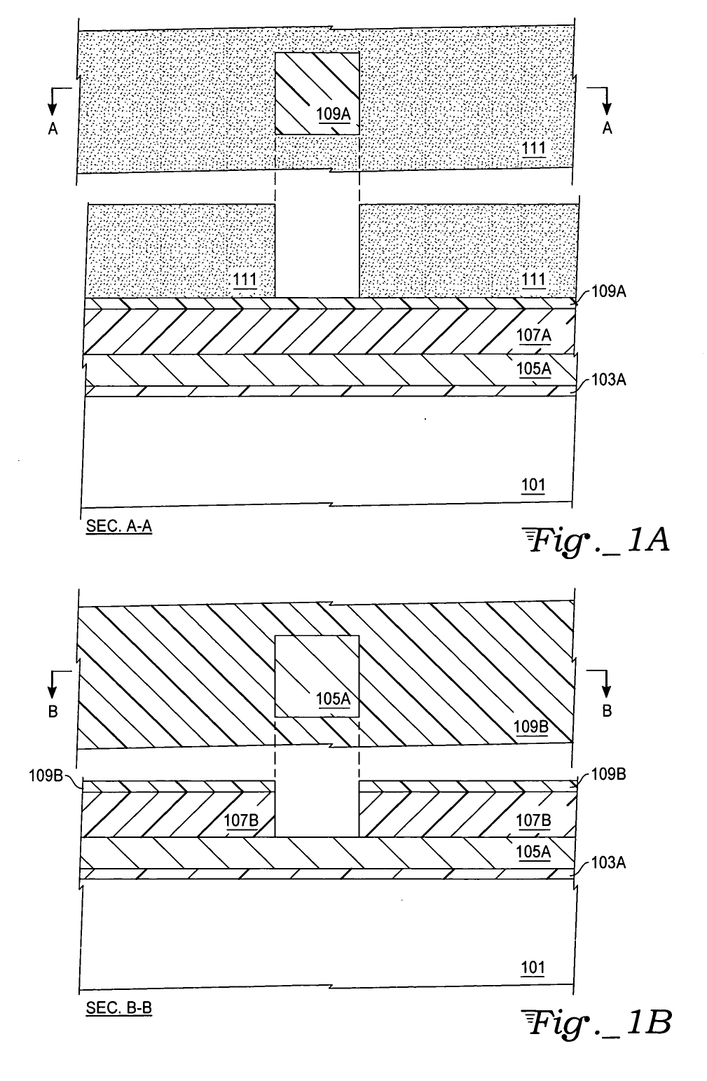

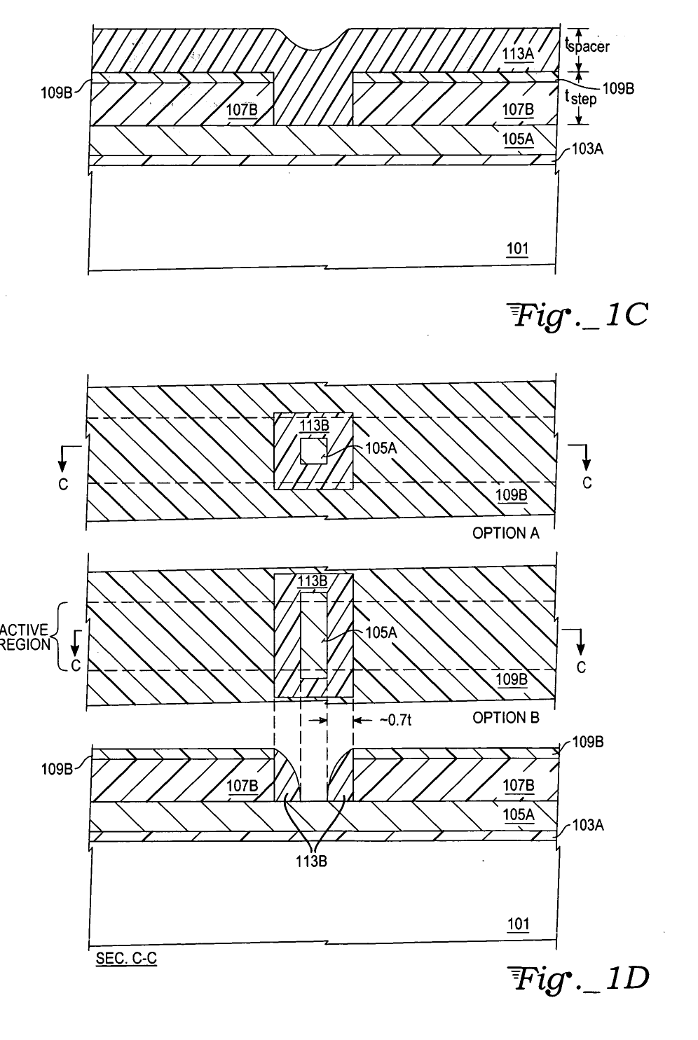

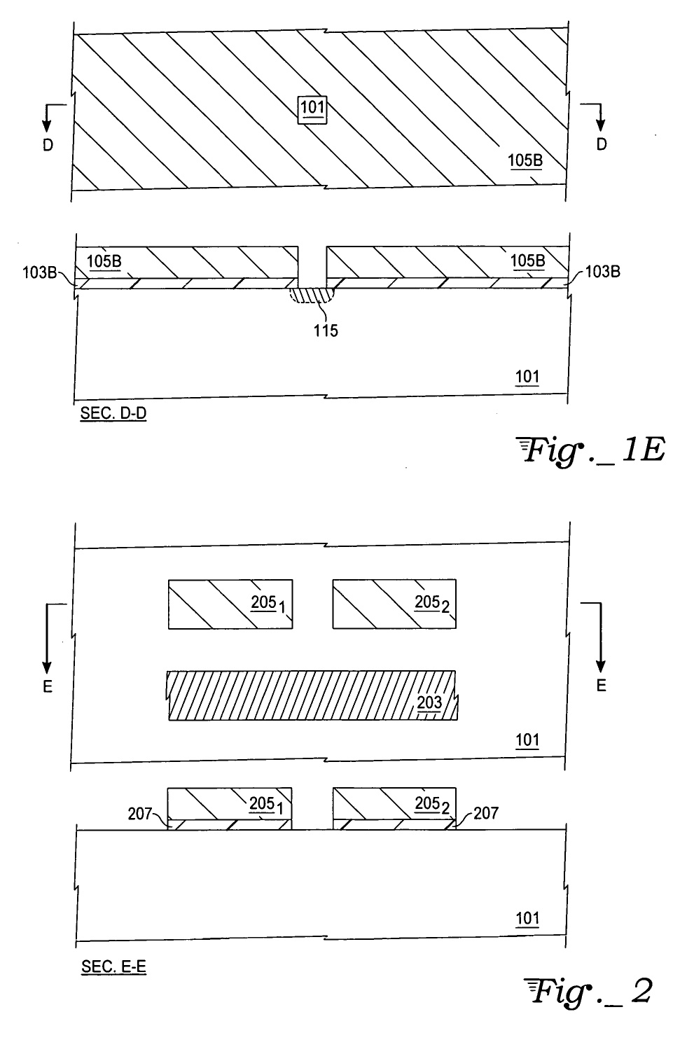

With reference to FIGS. 1A-1E, advanced spacer fabrication techniques are described in detail. The spacer fabrication technique is described with regard to a simplified topology to clearly describe and define various process steps. Although the simplified topology is a variation of a topology actually employed in the present invention, the simplified topology fabrication steps are described so as to more clearly describe the technique.

A cross-section A-A of FIG. 1A includes a substrate 101, a first dielectric layer 103A, a semiconductor layer 105A, a second dielectric layer 107A, a third dielectric layer 109A, and a patterned photoresist layer 111. The photoresist layer 111 contains an aperture. The substrate 101 may be comprised of various materials known in the semiconductor art. Such materials include silicon (or other group IV materials), compound semiconductors (e.g., compounds of elements, especially elements from periodic table groups III-V and II-VI), quartz reticles (e.g., with a deposited and annealed polysilicon layer or a deposited/sputtered metal layer over one surface), or other suitable materials.

In a specific exemplary embodiment, the substrate 101 is a p-type silicon wafer (or alternatively, a p-type well in a substrate). The first dielectric layer 103A is a silicon dioxide layer and is approximately 100 Å to 250 Å in thickness. The first dielectric layer 103A may be formed by a thermal oxidation technique or alternatively may be deposited by any of a variety of techniques such as atomic layer deposition (ALD), chemical vapor deposition (CVD), low-pressure CVD (LPCVD), plasma-enhanced CVD (PECVD), or plasma-assisted CVD (PACVD). In this specific exemplary embodiment, the semiconductor layer 105A is a polysilicon layer 500 Å to 1500 Å in thickness, while the second dielectric layer 107A and third dielectric layer 109A are substantially comprised of silicon dioxide and silicon nitride, respectively. The third dielectric layer 109A is approximately 60 Å to 100 Å in thickness while a thickness of the second dielectric layer 107A may be changed to accommodate a preferred “width” of eventual spacers to be formed, described infra.

The plan view of FIG. 1A indicates both a size of the aperture through the patterned photoresist layer 111 and visible layers. The layers visible at this stage of fabrication are the patterned photoresist layer 111 and the third dielectric layer 109A.

In cross-section B-B of FIG. 1B, a selective etchant, such as a highly selective dry etch or wet chemical etch is chosen to etch the third dielectric layer 109A and the second dielectric layer 107A, thus forming an etched third dielectric layer 109B and an etched second dielectric layer 107B. Etching of any listed underlying layer can occur through various wet-etch techniques (e.g., the second dielectric layer 107A may be etched in hydrofluoric acid, such as contained in a standard buffered oxide etch (BOE), or orthophosphoric acid) or dry etch techniques (e.g., reactive-ion-etching (RIE)). A skilled artisan will recognize that various dry etch or wet etch chemistries may be chosen which will readily etch, for example, a polysilicon layer while leaving a nitride layer essentially intact (or vice versa) or etch a nitride layer while leaving a silicon dioxide layer intact (or vice versa). Therefore, etches of one layer may be performed while leaving adjacent layers intact while avoiding tedious and critical timing steps. Layers comprised of materials dissimilar to the layer being etched thus serve as an etch stop. Such etching techniques are known in the semiconductor art. In this exemplary embodiment, one or more selective etchants are chosen such that there is a high selectivity of etch rate between the dielectric layers 107A, 109A and the underlying semiconductor layer 105A. Therefore, due to the selectivity of the etchant itself there is no need for critical timing as the semiconductor layer 105A acts as an etch stop for the dielectric layers 107A, 109A. The patterned photoresist layer 111 is stripped either after the third dielectric layer 109A is etched or after both the third dielectric layer 109A and the second dielectric layer 107A are etched, depending on etchant types and techniques used.

In FIG. 1C, a blanket dielectric spacer layer 113A is formed, for example, by CVD. In a specific exemplary embodiment, the dielectric spacer layer 113A is chosen to be chemically dissimilar to the underlying etched third dielectric layer 109B. For example, if the etched third dielectric layer 109B is chosen to be silicon nitride, then the dielectric spacer layer 113A may be chosen to be silicon dioxide. In this way, an etchant which is selective between silicon dioxide and silicon nitride allows the etched third dielectric (e.g., silicon nitride) layer 109B to act as an etch stop for etching spacers from the spacer dielectric (e.g., silicon dioxide) layer 113A.

A “width” of the spacer is dependent upon both a thickness of the deposited spacer layer and a step-height over which the deposited spacer layer is deposited. Since the spacer forms next to a given feature, the spacer is self-aligned with the feature and underlying features. Further, the spacer allows an etch or alignment step surrounding the given feature to be below a photolithographic limit of resolution since the etch or alignment is now based merely on a combined thickness, “t,” of the etched second dielectric layer 107B and the etched third dielectric layer 109B (i.e., a step-height of a proximate structure formed by these dielectric layers).

This spacer etch step is exemplified with reference to both the plan views (i.e., “Option A” and “Option B”) and the cross-sectional view C-C of FIG. 1D. In a case where dissimilar materials are used for the etched third dielectric layer 109B and the spacer dielectric layer 113A, a dielectric spacer 113B is formed on the aperture sidewalls by a selective etchant. The selective etchant is used to etch the dielectric spacer 113B without substantially affecting an integrity of any other layer. Etching of the spacer layer is performed such that substantially all horizontal surfaces (i.e., those parallel to the face of the substrate) are etched while leaving surfaces that are essentially vertical substantially intact. Such etches are accomplished by, for example, a reactive ion etch.

Generally, typical photolithographic techniques are limited by physical constraints of the photolithographic system involving actinic radiation wavelength, λ, and geometrical configurations of the projection system optics. According to Rayleigh's criterion,

$${L}_{r} = \frac{0.61 λ}{NA}$$

where NA is the numerical aperture of the optical system and is defined as NA=n sin α, where n is the index of refraction of the medium which the radiation traverses (usually air for this application, so n≅1) and α is a half-angle of divergence of the actinic radiation. For example, using deep ultraviolet (DUV) illumination with λ=193 nm, and NA=0.7, the lower limit of resolution is 168 nanometers (1680 Å). Techniques such as phase-shifted masks can extend this limit downward, but photomasks required employing this technique are extremely expensive and alignment errors may still be significant. The expense becomes greatly compounded with a realization that an advanced semiconductor process may employ more than 25 photomasks.

A “width” of the dielectric spacer 113B is dependent upon a thickness of the deposited spacer layer and a step height of proximate structures near where the spacer dielectric layer 113A is formed. The dielectric spacer 113B width is approximately 0.7·t_{spacer}, where “t_{spacer}” is the thickness of the dielectric spacer layer 113A, noted with reference to FIG. 1C, supra. Thus, the width of the spacers and, consequently any underlying features, may be fabricated to be extremely small. Therefore, the fabrication method described herein, and a device resulting from employing the method, may have components that are formed below a limit of resolution of optical photolithography by utilizing spacers to separate laterally displaced features (i.e., features that have spatial dimensions less than the limit of resolution in planes parallel to a face of a substrate or wafer, or “x-y” dimensions).

The plan views of FIG. 1D indicate how the dielectric spacer 113B can significantly reduce a size of an aperture. For example, compare a size of the aperture opening onto the semiconductor layer 105A in FIG. 1B with a size of the aperture now open to the semiconductor layer 105A in FIG. 1D. If the aperture in FIG. 1B were at the limit of resolution for a particular photolithographic stepper, in this case, 0.18 μm, and the thickness “t” of the combined dielectric layers 107B, 109B was 100 nm (i.e., 0.10 μm), then the aperture size “S” of FIG. 1D between the spacers 113B on opposing sidewalls of the original aperture (i.e., the aperture opening onto the semiconductor layer 105A) is
S=0.18 μm −[2·{0.7(0.10 μm)}]
S=0.04 μm
Thus, the aperture in FIG. 1D is significantly less than the limit of resolution of the stepper. The exemplary plan view of “Option A” indicates a simple square aperture formed by spacers over the semiconductor layer 105A. The “Option B” plan view indicates another exemplary rectangular shape formed over a buried active region. A skilled artisan can readily envision various other shapes and locations of spacers as well.

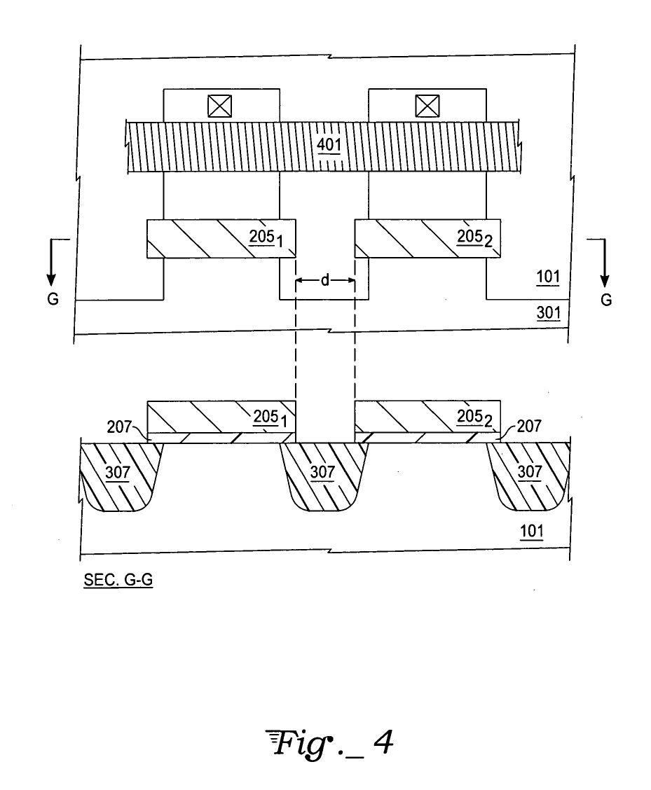

With reference to FIG. 1E, the semiconductor layer 105A and the first dielectric layer 103A have been etched, thus forming an etched semiconductor layer 105B and an etched first dielectric layer 103B, respectively. The etched third dielectric layer 109B has been removed. A size of the etch is roughly the size of the aperture formed within a periphery of the dielectric spacer 113B. The dielectric spacer 113B thus served as an etch mask. The dielectric spacer 113B also serves to limit an area for a subsequent dopant step, thereby forming an injector dopant region 115. The injector dopant region 115 may be formed by processes known to a skilled artisan and include techniques such as diffusion and ion implantation. Alternatively, the space between the two portions of the etched semiconductor layer 105B may be located over a field region, for example, a shallow trench isolation (STI) structure (not shown directly but see also FIG. 4). The fabrication processes employed and described with reference to FIGS. 1A-1E can be employed in advanced memory array design as described infra.

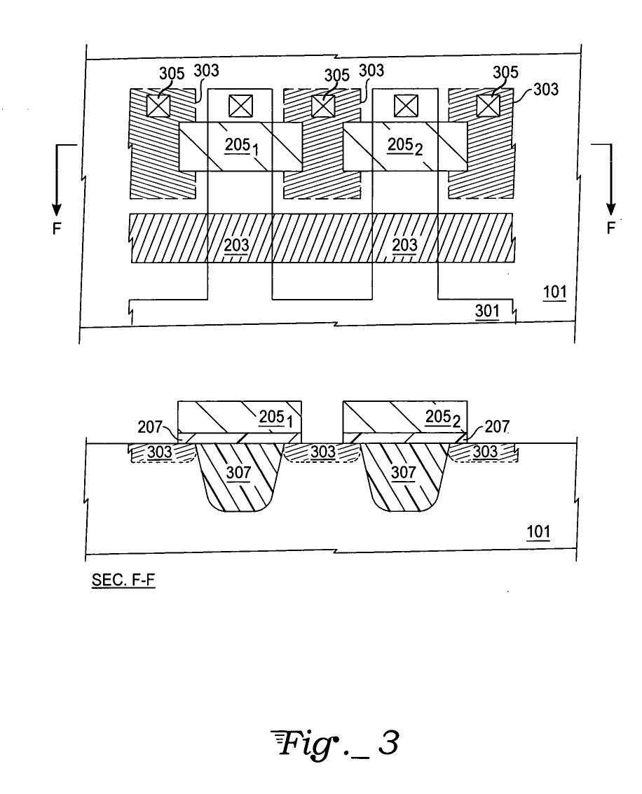

A cross-section E-E of FIG. 2 includes a control gate/wordline 203, a first floating gate 205₁, a second floating gate 205₂, and a gate oxide 207. A skilled artisan will quickly realize from the plan view of FIG. 2 how the spacer fabrication scheme incorporated in making the aperture in relation to FIGS. 1A-1E can be used with equal efficacy in fabricating the control gate/wordline 203 and floating gates 205₁, 205₂ with a spacing between the various components (i.e., a distance between a long axis of the control gate/wordline 203 and a nearest portion of either of the floating gates 205₁, 205₂) being less than a limit of resolution of optical photolithography. The spacing between the various components thus results from a spacer aperture used to form the components. Additionally, as would be recognized by one skilled in the art, an STI scheme (not shown) could be readily employed as well to isolate certain portions of the device. One adaptation to this simplified memory array layout incorporating the injector dopant region 115 of FIG. 1E will next be described with reference to FIG. 3. Another adaptation will be described with reference to FIG. 4.

With reference to cross-section F-F of FIG. 3, the first 205₁ and second 205₂ floating gates are disposed over shallow-trench isolation (STI) dielectric fill regions 307. As is known in the art, an STI structure effectively isolates, electrically, adjacent features on a substrate, one from another. The plan view of FIG. 3 includes an active region 301, a plurality of tunneling injector regions 303, and a plurality of tunneling injector contacts 305.

Each of the plurality of injector regions 303 is made by doping a localized area (e.g., through injector ion implantation) creating a subsurface highly-doped region for receiving bias from a nearby contact for charge generation, i.e., a tunneling injector. A control gate is formed from a nearby polysilicon stripe acting as the control gate/wordline 203. In a specific exemplary embodiment where the control gate/wordline 203 and the floating gates 205₁, 205₂ are fabricated from polysilicon, a separation of the polysilicon stripe (i.e., the control gate/wordline 203) from the polysilicon-polysilicon floating gates 205₁, 205₂ can be minimized by utilizing the spacer methods outlined supra with reference to FIG. 1A-1E.

The tunneling injector regions 303 are made in a manner similar to that described supra with respect to the injector dopant region 115 (FIG. 1E). Thus, each non-volatile memory transistor is fabricated to have a floating gate and a charge injector formed in one of the electrically isolated but adjacent tunneling injector regions 303.

The tunneling injector creates space charge flowing toward the bottom of the substrate 101 below the STI dielectric fill regions 307. Due to a proximity of the tunneling injector to the memory transistor, one or more of the electrodes of the memory transistor is biased to attract charge, e.g., holes. An impact caused by the holes upon the charged electrode gives rise to secondary charge carriers, such as electrons, by impact ionization. Impact ionization imparts sufficient energy on the secondary charge carriers for tunneling into one of the floating gates 205₁, 205₂. Current stimulation in the injector (essentially a fast diode), and controlled electrode bias in the transistor leads to placement of precise amounts of charge on one of the floating gates 205₁, 205₂. Mechanisms of charge injection into the gate oxide 207 and the floating gates 205₁, 205₂ (or from the floating gates 205₁, 205₂ into the gate oxide 207) and substrate 101 include: photo-emission, Fowler-Nordheim tunneling, or Zener or avalanche breakdown (assuming carriers in the substrate 101 acquire energies in excess of electron or hole barrier heights).

Additionally, conventional source and drain dopant regions are not required in the tunneling injector regions 303. A sufficient availability of majority carriers such as electrons or holes will be provided from the tunneling injector regions 303 and injected or tunneled into the appropriate floating gate 205₁, 205₂.

With reference to a plan view of FIG. 4, another exemplary embodiment includes the first 205₁, and second 205₂ floating gates disposed on either side of STI dielectric fill regions 307 (Section G-G). The STI structure electrically isolates adjacent features on the substrate 101, one from another. The plan view of FIG. 4 includes a portion of a select line 401. A width “d” in this embodiment is a minimum lithographic opening available with a given litho tool. A skilled artisan will recognize that the width “d” is not necessarily indicative of how accurately (or how closely) features may be located on a substrate. Other process variables, such as mask-to-mask and mask-to-level alignment errors can significantly increase a distance between how closely features may be placed together. Spacers (not shown but their application will be readily understandable with reference to FIGS. 1A-1E, supra) can reduce the distance between features by, for example, overlapping over an active region, and thus, allow fine placement of dopant regions. Spacers may be used in “pairs” (from a cross-sectional perspective where the spacers are formed around an internal periphery of an etched window), or singly (e.g., so as to overlap a portion of a dopant region to supply, for instance, masking while implanting a lightly doped drain (LDD) into an n-well).

In the foregoing specification, the present invention has been described with reference to specific embodiments thereof. It will, however, be evident to a skilled artisan that various modifications and changes can be made thereto without departing from the broader spirit and scope of the invention as set forth in the appended claims. For example, skilled artisans will appreciate that other types of semiconducting and insulating materials other than those listed may be employed. Additional particular process fabrication and deposition techniques, such as low pressure chemical vapor deposition (LPCVD), ultra-high vacuum CVD (UHCVD), and low pressure tetra-ethoxysilane (LPTEOS) may be readily employed for various layers and still be within the scope of the present invention. Although the exemplary embodiments describe particular types of dielectric and semiconductor materials, one skilled in the art will realize that other types of materials and arrangements of materials may also be effectively utilized and achieve the same or similar advantages. Also, the substrate itself may be comprised of a non-semiconducting material, for example, a quartz reticle with a deposited and doped polysilicon layer. Additionally, although the exemplary embodiments are described in terms of an EEPROM memory cell integrated circuit device, a person of ordinary skill in the art will recognize that other integrated circuit devices may readily benefit from the fabrication process described herein as well. The specification and drawings are, accordingly, to be regarded in an illustrative rather than a restrictive sense.

What is claimed is:

1. A method of fabricating an electronic integrated circuit device on a first surface of a substrate, comprising:
forming a semiconducting film layer over the first surface of the substrate;
forming a first dielectric film layer over the semiconducting film layer and creating a first aperture in the first dielectric film layer, the first aperture having sidewalls that are non-parallel to the first surface of the substrate;
forming spacers on the sidewalls of the first aperture such that a distance between spacers on opposing sidewalls of the first aperture is less than a limit of optical photolithography, the opposing spacers thus forming a second aperture;
creating a dopant region formed substantially within a portion of the semiconducting film layer underlying the second aperture; and
etching the portion of the semiconducting film layer underlying the second aperture thus forming a floating gate and a wordline.

2. The method of claim 1 wherein the dopant region is formed by ion implantation.

3. The method of claim 1 wherein the dopant region is formed by diffusing a dopant species.

4. The method of claim 1 further comprising forming a blanket dielectric film layer over the first surface of the substrate prior to forming the semiconducting film layer.

5. The method of claim 1 wherein the step of forming spacers on the sidewalls of the first aperture comprises:
forming a spacer dielectric film layer over the first dielectric film layer and a portion of the semiconducting film layer underlying the first aperture; and
etching regions of the spacer dielectric film layer that are essentially parallel to the first surface of the substrate while leaving regions of the spacer dielectric film layer that are essentially perpendicular to the first surface of the substrate, thus creating spacers.

6. The method of claim 5 wherein the step of etching regions of the spacer dielectric film layer is performed by a reactive ion etch (RIE).

7. The method of claim 5 wherein the spacer dielectric film is chosen such that a chemical etching property of the spacer dielectric film layer is dissimilar to a chemical etching property of the first dielectric film.

8. The method of claim 1 wherein the substrate is substantially comprised of a p-type silicon wafer.

9. The method of claim 1 wherein the semiconducting film layer is chosen to substantially comprised of polysilicon.

10. A method of fabricating an electronic integrated circuit device, comprising:
providing a substrate, the substrate being substantially comprised of silicon and having a first surface;
forming a first dielectric film layer over the first surface of the substrate;
forming a semiconducting film layer over the first dielectric film layer;
forming a second dielectric film layer over the semiconducting film layer and creating a first aperture in the second dielectric film layer, the first aperture having sidewalls that are non-parallel to the first surface of the substrate;
forming a spacer film layer over the second dielectric film layer and a portion of the semiconducting film layer underlying the first aperture;
etching regions of the spacer film layer that are essentially parallel to the first surface of the substrate while leaving regions of the spacer film layer that are essentially perpendicular to the first surface of the substrate, the step of etching regions of the spacer film layer thus creating spacers on the sidewalls of the first aperture, a distance between spacers on opposing sidewalls of the first aperture is less than a limit of optical photolithography, the opposing spacers thus forming a second aperture;
creating a dopant region formed substantially within a portion of the semiconducting film layer underlying the second aperture; and
etching the portion of the semiconducting film layer underlying the second aperture thus forming a floating gate and a wordline.

11. The method of claim 10 wherein the step of etching regions of the spacer film layer is performed by a reactive ion etch (RIE).

12. The method of claim 10 wherein the spacer film layer is selected to be comprised of a dielectric material.

13. The method of claim 12 wherein the dielectric material is chosen such that a chemical etching property of the dielectric material is dissimilar to a chemical etching property of the second dielectric film.

14. The method of claim 10 wherein the silicon substrate is substantially comprised of a p-type silicon wafer.

15. The method of claim 10 wherein the semiconducting film layer is chosen to substantially comprised of polysilicon.

16. The method of claim 10 wherein the doped region is formed by ion implantation.

17. The method of claim 1 wherein the doped region is formed by diffusing a dopant species.

18. A memory cell array, comprising:
a plurality of floating gates forming a portion of a memory transistor, the plurality of floating gates being comprised substantially of a first semiconducting material and being constructed over a substrate;
a gate dielectric material interposed between the plurality of floating gates and the substrate;
a wordline being comprised substantially of the first semiconducting material and being constructed over the substrate and in close proximity to the plurality of floating gates, the wordline arranged such that a distance between a long axis of the wordline and a nearest portion of any of the plurality of floating gates is less than a limit of resolution of optical lithography; and
an injector dopant region disposed in close relationship to each of the plurality of floating gates.

19. The memory cell array of claim 18 wherein the substrate is comprised substantially of p-type silicon.

20. The memory cell array of claim 18 wherein the semiconducting material is comprised substantially of polysilicon.

21. The memory cell array of claim 18 wherein the gate dielectric material is comprised substantially of silicon dioxide.

22. The memory cell array of claim 18 wherein the injector dopant region is disposed between each pair of the plurality of floating gates.

23. A memory cell array, comprising:
a plurality of floating gates forming a portion of a memory transistor, the plurality of floating gates being comprised substantially of a first semiconducting material and being constructed over a substrate;
a gate dielectric material interposed between the plurality of floating gates and the substrate;
a select line being comprised substantially of the first semiconducting material and being constructed over the substrate and in close proximity to the plurality of floating gates, the select line arranged such that a distance between a long axis of the select line and a nearest portion of any of the plurality of floating gates is less than a limit of resolution of optical lithography; and
an injector dopant region disposed in close relationship to each of the plurality of floating gates.

24. The memory cell array of claim 23 wherein the substrate is comprised substantially of p-type silicon.

25. The memory cell array of claim 23 wherein the semiconducting material is comprised substantially of polysilicon.

26. The memory cell array of claim 23 wherein the gate dielectric material is comprised substantially of silicon dioxide.

27. The memory cell array of claim 23 wherein the injector dopant region is disposed between each pair of the plurality of floating gates.

28. A method of fabricating an electronic integrated circuit device on a first surface of a substrate, comprising:
forming a semiconducting film layer over the first surface of the substrate;
forming a first dielectric film layer over the semiconducting film layer and creating a first aperture in the first dielectric film layer, the first aperture having sidewalls that are non-parallel to the first surface of the substrate;
forming spacers on the sidewalls of the first aperture such that a distance between spacers on opposing sidewalls of the first aperture is less than a limit of optical photolithography, the opposing spacers thus forming a second aperture;
creating a dopant region formed substantially within a portion of the semiconducting film layer underlying the second aperture; and
etching the portion of the semiconducting film layer underlying the second aperture thus forming a floating gate and a select line.

29. The method of claim 28 further comprising forming a blanket dielectric film layer over the first surface of the substrate prior to forming the semiconducting film layer.

30. The method of claim 28 wherein the step of forming spacers on the sidewalls of the first aperture comprises:
forming a spacer dielectric film layer over the first dielectric film layer and a portion of the semiconducting film layer underlying the first aperture; and
etching regions of the spacer dielectric film layer that are essentially parallel to the first surface of the substrate while leaving regions of the spacer dielectric film layer that are essentially perpendicular to the first surface of the substrate, thus creating spacers.

31. The method of claim 30 wherein the step of etching regions of the spacer dielectric film layer is performed by a reactive ion etch (RIE).

32. The method of claim 30 wherein the spacer dielectric film is chosen such that a chemical etching property of the spacer dielectric film layer is dissimilar to a chemical etching property of the first dielectric film.
